(19) United States
(12) Patent Application Publication
(10) Pub. No.: US 2025/0040203 A1
(43) Pub. Date: Jan. 30, 2025

(54) METHOD FOR FORMING ISOLATION TRENCH, AND ISOLATION TRENCH

(71) Applicant: Silergy Semiconductor Technology (Hangzhou) LTD, Hangzhou (CN)

(72) Inventors: Xufeng Li, Hangzhou (CN); Huan Wang, Hangzhou (CN); Qianwen Wang, Hangzhou (CN)

(21) Appl. No.: 18/773,979

(22) Filed: Jul. 16, 2024

(30) Foreign Application Priority Data
Jul. 26, 2023 (CN) 202310930811.0

(51) Int. Cl. H01L 29/06; H01L 21/762; H01L 21/768

(52) U.S. Cl. CPC H01L 29/0684; H01L 21/76232; H01L 21/76816; H01L 21/76831

(57) ABSTRACT

A method of forming an isolation trench, can include: forming a trench in a substrate, the trench extending from a first surface of the substrate to an interior of the substrate; and forming at least two layers of different filling materials in the trench to completely fill the trench, where a step coverage of each layer of filling material is better than a step coverage of the previous layer of filling material.

### RELATED APPLICATIONS

This application claims the benefit of Chinese Patent Application No. 202310930811.0, filed on Jul. 26, 2023, which is incorporated herein by reference in its entirety.

### FIELD OF THE INVENTION

The present invention generally relates to the field of semiconductor technology, and more particularly to isolation trenches, and methods of forming isolation trenches.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

FIG. 1 is a cross-sectional view of an example insulation trench, in accordance with embodiments of the present invention.

FIG. 2 is a cross-sectional view an example conductive trench, in accordance with embodiments of the present invention.

FIG. 3 is a flow diagram of a first example method for forming an isolation trench, in accordance with embodiments of the present invention.

FIGS. 4A-4C are cross-sectional views of the various stages of a method of forming a first example isolation trench, in accordance with embodiments of the present invention.

FIG. 5 is a flow diagram of a second example method for forming an isolation trench, in accordance with embodiments of the present invention.

FIGS. 6A-6C are cross-sectional views of the some stages of a method of forming a second example isolation trench, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die are mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

The manufacturing process of semiconductor integrated circuits mainly can include the formation of devices such as transistors in the active region of the surface of the semiconductor substrate. These devices need to be isolated from each other through isolation structures. Both trench isolation structure and field oxide isolation structure are often used to isolate the active region of semiconductor substrate.

BCD devices can include bipolar junction transistors (BJT), complementary metal-oxide-semiconductor (CMOS), and double-diffused metal-oxide-semiconductor (DMOS). BJT can be used for processing analog signals, CMOS for controlling digital signals, and DMOS for drivers with high voltage or high power output. Accordingly, BCD generally devices have advantages of high transconductance, high voltage resistance, good noise resistance, high integration, and low power consumption by combining the performance of BJT, CMOS, and DMOS.

Common isolation structures in BCD devices are deep trench isolation (DTI) structures, which are trenches with high aspect ratios. When the metal layer is filled in trench, air gaps in the metal layer can be generated, which affect the performance of BCD. For example, if air gaps are too large or the positions of the air gaps change, it may affect the thickness of the insulation layer on sidewalls of the trench, and thus affect the voltage resistance of BCD devices, particularly for automotive BCD chip products, which will have reliability risks.

Particular embodiments provide an isolation trench that can include a substrate, a trench, extending from a first surface of the substrate to an interior of the substrate, at least two layers of different filling materials that are filled in the trench, where a step coverage of each layer of filling material is better than a step coverage of the previous layer of filling material. The fluidity of each layer of filling material may be greater than that of the previous layer of filling material. Further, a first layer of filling material can cover on both side surfaces and bottom surface of the trench, starting from the second layer of filling material, and each layer of filling material can cover a surface of the previous layer of filling material. The first layer of filling material can be an insulation layer. The isolation trench can include an insulation trench and a conductive trench, and the following is an example of two layers of filling materials.

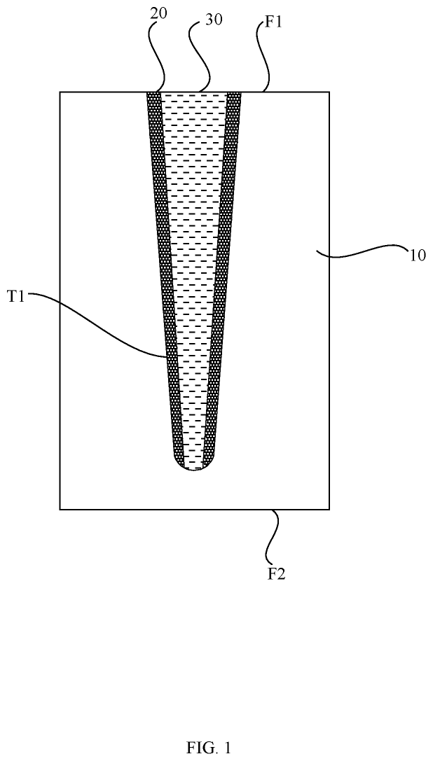

Referring now to FIG. 1, shown is a cross-sectional view of an example insulation trench, in accordance with embodiments of the present invention. The insulation trench can include substrate 10, trench T1, insulation layer 20, and auxiliary layer 30. Substrate 10 can include surface F1 and surface F2 that are opposite to each other. Trench T1 may extend from surface F1 of substrate 10 to the interior of substrate 10. Insulation layer 20 can be located on both side surfaces of trench T1 and bottom surface of trench T1 to define an internal space. Auxiliary layer 30 may be filled in the internal space. Auxiliary layer 30 may have good step coverage to completely fill the internal space, and the step coverage of the auxiliary layer can be better than a step coverage of the insulation layer.

It should be noted that “good” step coverage indicates that the thickness of auxiliary layer 30 formed on each surface of trench T1 is uniform. For example, when auxiliary layer 30 is filled in trench T1 or hole, the formation speed of auxiliary layer 30 at an opening of trench T1 may be consistent with the formation speed of auxiliary layer 30 at a bottom surface of trench T1. This can thereby avoid the formation of air gaps caused by the opening of trench T1 being covered by auxiliary layer 30 first, the formation speed of auxiliary layer 30 on both side surfaces and bottom surface of trench T1 may be the same, and the thickness of auxiliary layer 30 formed on both side surfaces and bottom surface of trench T1 can be uniform. The uniform thickness of auxiliary layer 30 can be determined by measuring the surface roughness of auxiliary layer 30. When the surface roughness of auxiliary layer 30 is lower than a specific value (e.g., 1 nm), it may be determined that the thickness of auxiliary layer 30 is uniform. The surface roughness measurement of auxiliary layer 30 can be achieved by atomic force microscopy (AFM).

In this example, a depth of trench T1 can be greater than 20 um, a depth to width ratio of trench T1 may be greater than 10, and trench T1 can be a DTI structure. A thickness of insulation layer 20 can be greater than 150 angstroms and less than 250 angstroms. For example, the thickness of insulation layer 20 can be 200 angstroms. Insulation layer 20 can cover both sides surfaces and bottom surface of trench T1, and auxiliary layer 30 may be surrounded by insulation layer 20 and contact with insulation layer 20. The internal space can be filled with auxiliary layer 30, and the fluidity of auxiliary layer 30 may be greater than that of insulation layer 20.

The material of substrate 10 may include silicon, and substrate 10 may be of a first doping type. For example, the first doping type is one of N-type and P-type, and a second doping type is the other of N-type and P-type. In order to form an N-type semiconductor layer or region, N-type dopants can be implanted into substrate 10, which can, e.g., be phosphorus (P) or arsenic (As). In order to form a P-type semiconductor layer or region, P-type dopant can be implanted into substrate 10, e.g., boron (B). In one example, substrate 10 is N-type.

The materials of insulation layer 20 may include SiOₓ, SiON, SiOC, AlOₓ, HfO₂, SiNₓ, SiCBN, SiCN, SiOCN, Y₂O₃, Y₂TiO₅, Yb₂O₃, ZrO₂, TiO₂, andTa₂O₅ or their combination. The material of auxiliary layer 30 may include tungsten (W). The materials of the aforementioned insulation layer 20 and auxiliary layer 30 are only listed and are not intended to limit the present application.

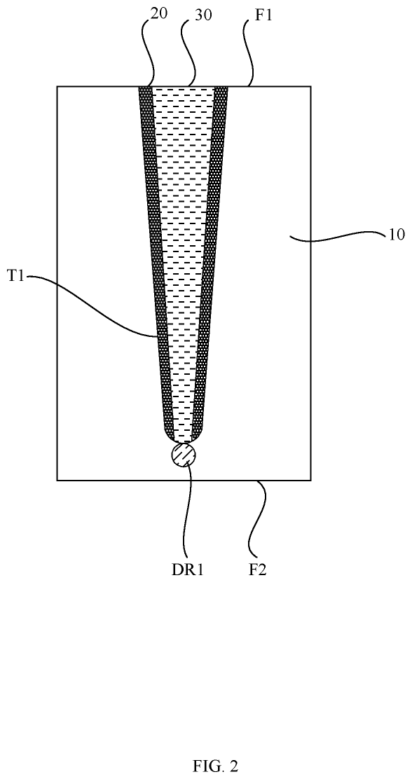

Referring now to FIG. 2, shown is a cross-sectional view an example conductive trench, in accordance with embodiments of the present invention. In this particular example, the conductive trench can include substrate 10, trench T1, insulation layer 20, and auxiliary layer 30. The structure of substrate 10 and trench T1 may be the same as that of substrate 10 and trench T1 shown in FIG. 1, without repeating the similarities between the conductive trench shown in FIG. 2 and the insulation trench shown in FIG. 1.

Insulation layer 20 can be arranged on both side surfaces of trench T1, and insulation layer 20 located on both sides of trench T1 may define an internal space. Auxiliary layer 30 can be filled in the internal space and contacts substrate 10. For example, auxiliary layer 30 may have good step coverage to completely fill the internal space, and the step coverage of the auxiliary layer is better than a step coverage of the insulation layer and the material of auxiliary layer 30 is conductive material. Because there is no insulation layer 20 at the bottom of trench T1, the internal space of the conductive trench may be different from that of the insulation trench.

For example, auxiliary layer 30 can be located between insulation layers 20 on both sides of trench T1. Auxiliary layer 30 can connect a reference voltage to make substrate 10 externally connected; that is, substrate 10 may connect the reference voltage through auxiliary layer 30. The reference voltage can be the positive or negative voltage of the working voltage of the semiconductor device. Conductive materials can include tungsten (W), copper (Cu), aluminum (Al), titanium (Ti), cobalt (Co), tantalum (Ta), nickel (Ni), gold (Au), or silver (Ag). Materials with good filling performance, good fluidity, low stress impact, and good contact with the interface of insulation layer 20 can also be used as conductive materials in certain embodiments.

In this particular example, the conductive trench can also include doped region DR1. Doping region DR1 may be located in substrate 10 and adjacent to bottom portion of trench T1. Further, doping region DR1 can be adjacent to insulation layer 20 and auxiliary layer 30, and may come into contact with insulation layer 20 and auxiliary layer 30. Doping region DR1 may remain separated by a certain distance from surface F2. For example, doping region DR1 can be the first doping type.

Particular embodiments may also provide a method of forming an isolation trench, which can include forming a trench in a substrate, where the trench extends from a first surface of the substrate to an interior of the substrate; and forming at least two layers of different filling materials in the trench to completely fill the trench. For example a step coverage of each layer of filling material can be better than a step coverage of the previous layer of filling material and the fluidity of each layer of filling material may be greater than that of the previous layer of filling material. Further, the first layer of filling material can be formed to cover on both side surfaces and bottom surface of the trench, and starting from the second layer of filling material, each layer of filling material can be formed to cover a surface of the previous layer of filling material, where the first layer of filling material can be an insulation layer. The following is an example of forming two layers of filling material in the trench.

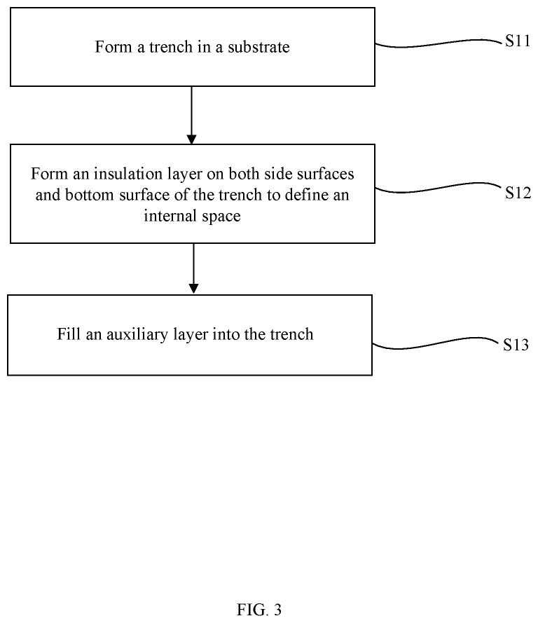

Referring now to FIG. 3, shown is a flow diagram of a first example method of forming an isolation trench, in accordance with embodiments of the present invention. In this particular example, the method of forming the isolation trench can include steps S11 to S13. The following example illustrates the example method of forming an isolation trench in order to manufacture the insulation trench as shown in FIG. 1.

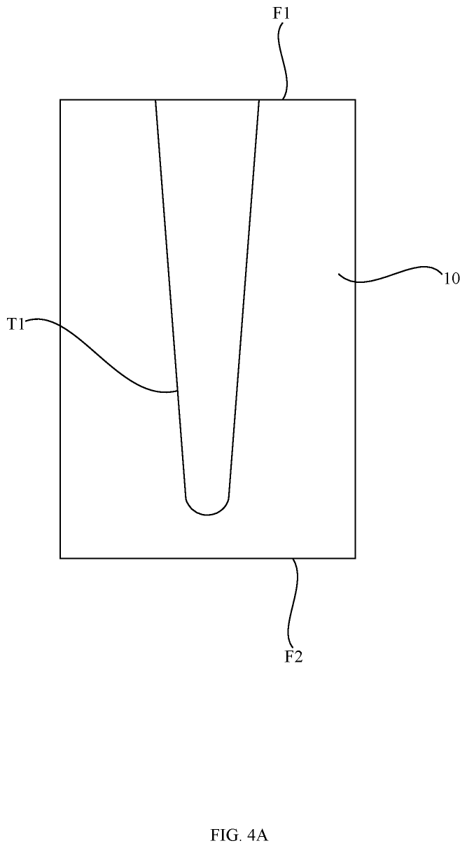

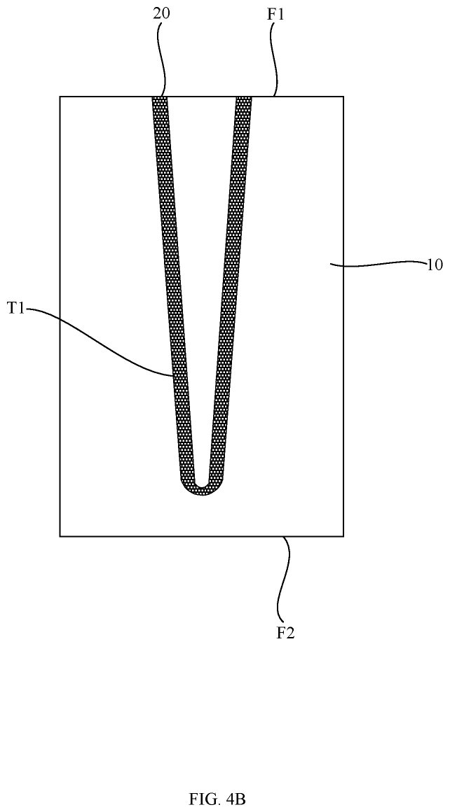

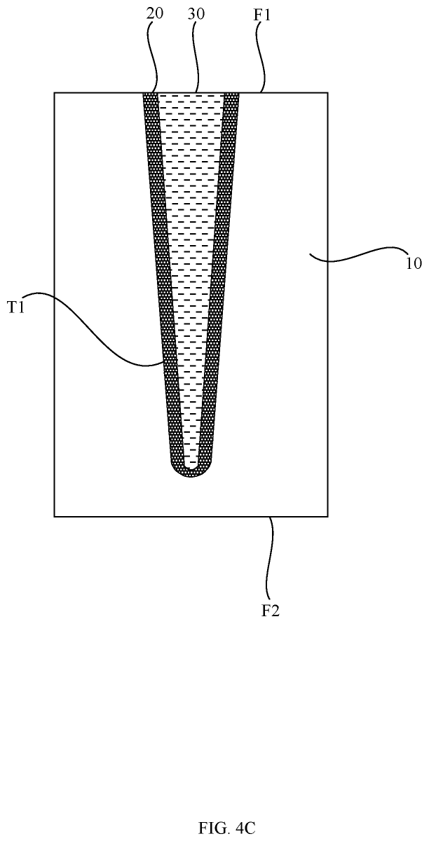

At S11, trench T1 can be formed in substrate 10. For example, as shown in FIG. 4A, trench T1 may extend from surface F1 to surface F2, and terminate in substrate 10. In an example, a patterned photoresist layer may be formed on substrate 10, and the patterned photoresist layer can be used as a mask. Dry etching (plasma) may be used to etch from the first surface of substrate 10 to an interior of substrate 10, in order to form trench T1 in substrate 10, and the patterned photoresist layer may be removed. For example, by adjusting the power, gas concentration, and etching time of dry (plasma) etching, the depth and opening width of the trench can be controlled.

In another example, a dielectric layer can be formed on substrate 10, and a photoresist layer formed on the dielectric layer. The dielectric layer can be etched from the opening of the photoresist mask and stopped at the first surface of substrate 10, in order to form an opening penetrating the dielectric layer. The dielectric layer with the opening may be used as a hard mask. The above-mentioned etching can be inductively coupled plasma reactive-ion etching (ICP-RIE) or wet etching, and the material of the dielectric layer can be the same as that of insulation layer 20. After forming the hard mask, the photoresist layer may be removed by solvent dissolution or ashing, and trench T1 can be formed in substrate 10 by etching from surface F1 to the interior of substrate 10 based on the hard mask. After the step of forming trench T1, the aforementioned hard mask can be removed by selective etching agents. For example, the depth and opening width of trench T1 can be controlled by adjusting the concentration of the etching solution and etching time.

The materials of insulation layer 20 may include SiOₓ, SiON, SiOC, AlOₓ, HfO₂, SiNₓ, SiCBN, SiCN, SiOCN, Y₂O₃, Y₂TiO₅, Yb₂O₃, ZrO₂, TiO₂, and Ta₂O₅ or their combination. The material of auxiliary layer 30 may include tungsten (W). The materials of the aforementioned insulation layer 20 and auxiliary layer 30 are only examples of materials that may be used in certain embodiments.

At S12, insulation layer 20 may be formed on both side surfaces and bottom surface of trench T1 to define an internal space. For example, insulation layer 20 can be formed on the bottom surface and side surfaces of trench T1 and surface F1 by chemical vapor deposition (CVD) or thermal oxidation process. Next, insulation layer 20 can be etched by reactive ion etching to remove insulating layer 20 located on substrate 10 and leave insulating layer 20 (see, e.g., FIG. 4B), which defines the internal space. For example, a thickness of insulation layer 20 can be greater than 150 angstroms and less than 250 angstroms, and the thickness of insulation layer 20 can be 200 angstroms.

At S13, auxiliary layer 30 may be filled into trench T1. For example, auxiliary layer 30 can be formed in the internal space to fill trench T1, such that auxiliary layer 30 is adjacent to insulation layer 20. The methods for forming auxiliary layer 30 may include sputtering, vapor deposition, chemical vapor deposition, electroplating, or molecular beam epitaxy. Further, the atoms of auxiliary layer 30 can diffuse from surface F1 to the bottom of trench T1. The atoms of auxiliary layer 30 may attach to surface F1 of substrate 10 and gradually fill the entire trench T1, thereby auxiliary layer 30 on trench T1 and surface F1 of substrate 10 is formed. Next, auxiliary layer 30 on surface F1 can be etched using a reactive ion etching process, leaving auxiliary layer 30, as shown in FIG. 4C.

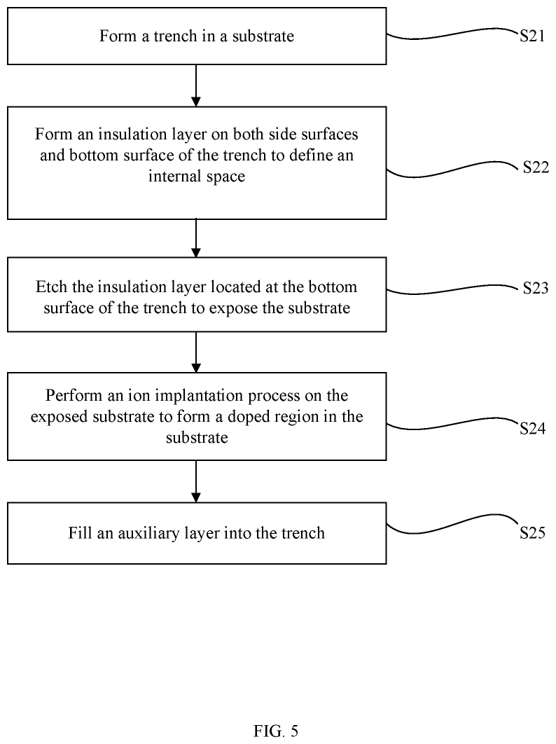

Referring now to FIG. 5, shown is a flow diagram of a second example method of forming an isolation trench, in accordance with embodiments of the present invention. In this particular example, the method of forming the isolation trench can include steps S21 to S25, where steps S21 to S22 are the same as steps S11 to S12 shown in FIG. 1. The following example illustrates the method of forming an isolation trench as shown in FIG. 5 to manufacture a conductive trench as shown in FIG. 2.

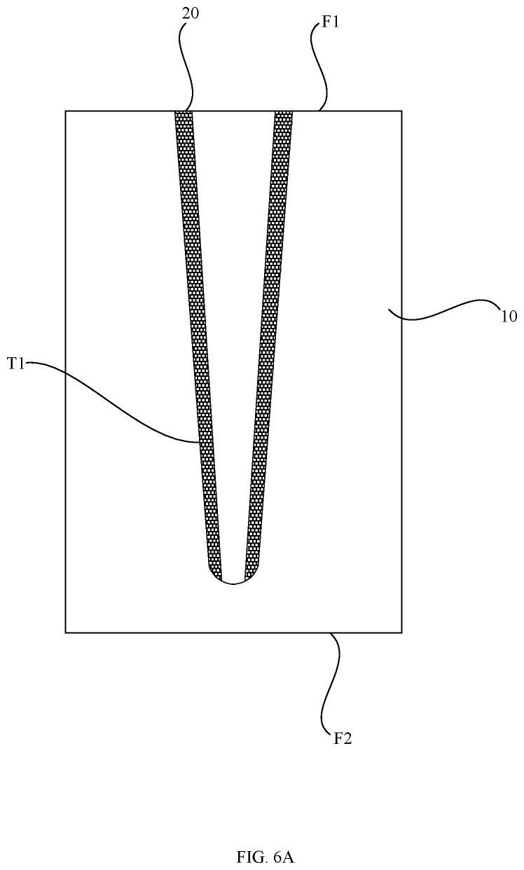

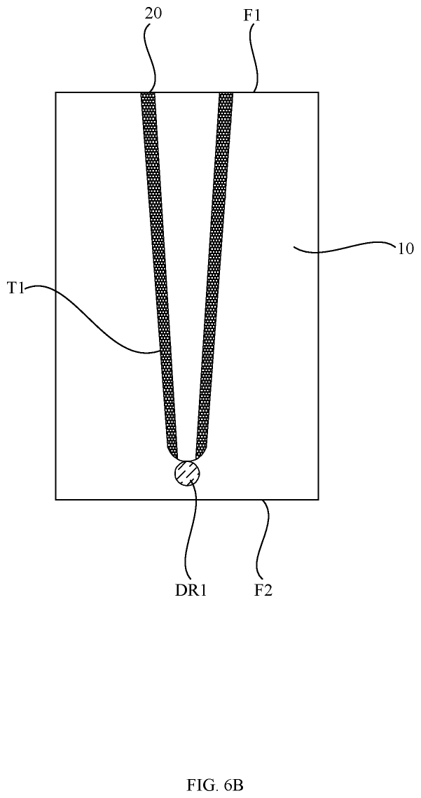

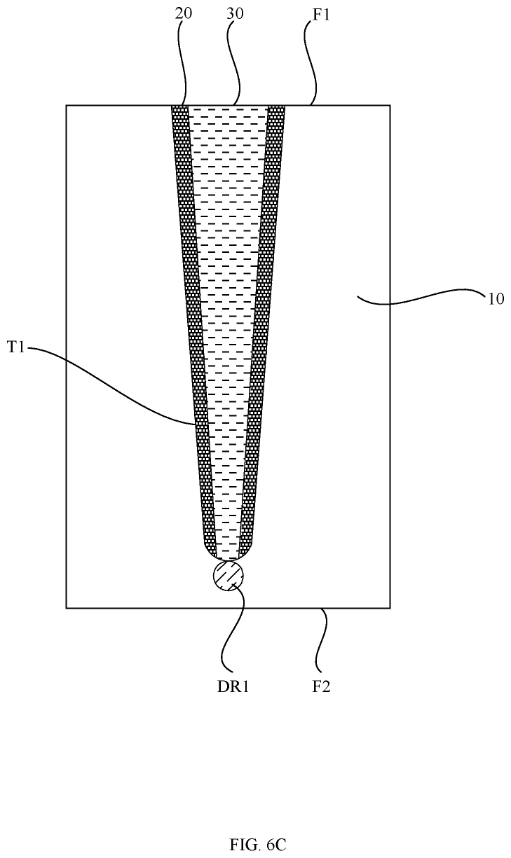

At S23, insulation layer 20 located at the bottom surface of trench T1 can be etched in order to expose substrate 10. For example, a mask layer with an opening may be formed on surface F1, which corresponds to trench T1. The width of the opening can be smaller than the distance between two insulation layers 20 on both side surfaces of trench T1. Next, insulation layer 20 located at the bottom surface of trench T1 may be etched by reactive ions to expose substrate 10, and the mask layer removed to leave insulating layer 20 (see, e.g., FIG. 6A), which defines the internal space. Due to the removal of insulation layer 20 at the bottom surface of trench T1, the internal space of the conductive trench may differ from that of the insulation trench.

At S24, an ion implantation process on the exposed substrate 10, in order to form doped region DR1 in substrate 10. For example, the ion implantation process(es) may be performed on the exposed substrate 10 by an ion implantation device to form doping region DR1 in substrate 10 adjacent to the bottom surface of trench T1 (see, e.g., FIG. 6B), in order to reduce the contact resistance of substrate 10.

At S25, auxiliary layer 30 may be filled into trench T1. For example, as shown in FIG. 6C, auxiliary layer 30 can be formed in the internal space to fill trench T1. Auxiliary layer 30 may contact substrate 10 and can be surrounded by insulation layer 20, such that substrate 10 may have an external function to receive the reference voltage. Thereby, the crosstalk caused by free charges can be eliminated.

In particular embodiments, a method of forming an isolation trench may prevent formation of air gaps in the auxiliary layer by forming the auxiliary layer with good step coverage. In this way, a deep trench isolation structure without an air gap can be achieved. In addition, particular embodiments may be applied to the deep trench isolation structure of BCD devices to solve the air gap problem in the current deep trench isolation structure of BCD devices. This can improve the electrical performance failure caused by insufficient voltage resistance due to the thin insulation layer on the side surfaces of the deep trench caused by the air gap problem, as well as the potential reliability failure risk caused by the disordered grain arrangement or charge accumulation caused by the excessive stress introduced by the air gap problem.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A method of forming an isolation trench, the method comprising:
a) forming a trench in a substrate, the trench extending from a first surface of the substrate to an interior of the substrate; and
b) forming at least two layers of different filling materials in the trench to completely fill the trench,
c) wherein a step coverage of each layer of filling material is better than a step coverage of the previous layer of filling material.

2. The method of claim 1, wherein a fluidity of each layer of filling material is greater than that of a previous layer of filling material.

3. The method of claim 1, wherein a first layer of filling material is formed to cover both side surfaces and bottom surface of the trench, and starting from the second layer of filling material, each layer of filling material is formed to cover a surface of the previous layer of filling material.

4. The method of claim 1, wherein a first layer of filling material comprises an insulation layer.

5. The method of claim 1, wherein when the filling material comprises two layers, the step of forming at least two layers of different filling materials in the trench comprises:
a) forming an insulation layer on both side surfaces and bottom surface of the trench to define an internal space; and
b) filling an auxiliary layer in the trench to completely fill the internal space, wherein a step coverage of the auxiliary layer is better than a step coverage of the insulation layer.

6. The method of claim 5, wherein the auxiliary layer comprises tungsten.

7. The method of claim 5, wherein before the step of filling the auxiliary layer in the trench, the method further comprises etching the insulation layer located on the bottom surface of the trench to expose the substrate.

8. The method of claim 7, further comprising performing an ion implantation process on the exposed substrate to form a doped region in the substrate.

9. The method of claim 7, wherein when the auxiliary layer comprises a conductive material, and the auxiliary layer is connected to a reference voltage to support the substrate being externally connected.

10. The method of claim 5, wherein the filling the auxiliary layer comprises using a chemical vapor deposition process.

11. The method of claim 1, wherein a depth to width ratio of the trench is greater than 10.

12. The method of claim 1, wherein a depth of the trench is greater than 20 um.

13. The method of claim 1, wherein the isolation trench is applied to a BCD (BJT-CMOS-DMOS) device, wherein the BCD device comprises a bipolar junction transistor (BJT), a complementary metal oxide semiconductor (CMOS), and a double diffused metal oxide semiconductor (DMOS).

14. An isolation trench, comprising:
a) a substrate;
a) a trench extending from a first surface of the substrate to an interior of the substrate; and
b) at least two layers of different filling materials that are filled in the trench,
c) wherein a step coverage of each layer of filling material is better than a step coverage of the previous layer of filling material.

15. The isolation trench of claim 14, wherein a fluidity of each layer of filling material is greater than that of a previous layer of filling material.

16. The isolation trench of claim 14, wherein a first layer of filling material covers both side surfaces and bottom surface of the trench, and starting from the second layer of filling material, each layer of filling material covers a surface of the previous layer of filling material.

17. The isolation trench of claim 14, wherein a first layer of filling material comprises an insulation layer.

18. The isolation trench of claim 14, wherein when the filling material comprises two layers, the at least two layers of different filling materials comprises:
a) an insulation layer provided on both side surfaces and bottom surface of the trench to define an internal space; and
b) an auxiliary layer filled in the internal space, wherein a step coverage of the auxiliary layer is better than a step coverage of the insulation layer.

19. The isolation trench of claim 14, wherein when the filling material comprises two layers, the at least two layers of different filling materials comprises:
a) an insulation layer provided on both side surfaces of the trench to define an internal space; and
b) an auxiliary layer filled in the internal space and contacting the substrate, wherein a step coverage of the auxiliary layer is better than a step coverage of the insulation layer and the material of the auxiliary layer is configured as conductive material.

20. The isolation trench of claim 18, wherein the auxiliary layer comprises tungsten.
